(19) United States
(12) Patent Application Publication
(10) Pub. No.: US 2024/0431025 A1
(43) Pub. Date: Dec. 26, 2024

(54) CORROSION RESISTANT SINGLE DAMASCENE INTERCONNECTS

(71) Applicant: INTERNATIONAL BUSINESS MACHINES CORPORATION, Armonk, NY (US)

(72) Inventors: Takeshi Nogami, Schenectady, NY (US); Daniel Charles Edelstein, White Plains, NY (US); Wei-Tsu Tseng, Hopewell Junction, NY (US); James J. Kelly, Schenectady, NY (US); Donald Francis Canaperi, Bridgewater, CT (US)

(21) Appl. No.: 18/214,159

(22) Filed: Jun. 26, 2023

(51) Int. Cl. H05K 1/11; C23C 14/08; C23C 14/34; H05K 1/09; H05K 3/42

(52) U.S. Cl. CPC H05K 1/115; C23C 14/081; C23C 14/34; H05K 1/09; H05K 3/42

(57) ABSTRACT

A single-damascene interconnect comprises a first conductor line and a second conductor line. The single-damascene interconnect also comprises a via connecting the first conductor line and second conductor line. The via is filled with a low resistivity metal conductor. The low resistivity metal conductor has high corrosion resistance. The metal conductor is not the same material as the first or second conductor lines.

### BACKGROUND

The present invention relates to conductive vias, and more specifically, to forming conductive vias in a single damascene process.

Vias may be used in interconnects to connect multiple conductor lines of a product. Some vias may be formed using a dual damascene process, during which both a via and top conductor line are formed in a single fill process. Some vias are formed using a single damascene process, during with a via is formed using a first fill process and a top conductor line is formed using a second, separate fill process. Single damascene processes typically include a planarization step after the first fill process to prepare the interconnect for formation of a top layer dielectric and the top conductor line.

### SUMMARY

Some embodiments of the present disclosure can be illustrated as a single-damascene interconnect. The single-damascene interconnect may comprise a first conductor line and a second conductor line. The single-damascene interconnect may also comprise a via that connects the first conductor line and second conductor line. The via may be filled with a low resistivity metal conductor with high corrosion resistance. The metal conductor may be a different material than the first and second conductor lines.

### BRIEF DESCRIPTION OF THE DRAWINGS

FIG. 1 depicts a single damascene interconnect that comprises a via filled with a noble metal.

FIG. 2 depicts a single damascene interconnect that comprises a via filled with an intermetallic conductor.

FIGS. 3A-3J depict example stages of a process of forming a single damascene interconnect that comprises a via filled with an intermetallic conductor.

FIG. 4 depicts a single damascene interconnect that comprises a pre-deposited diffusion barrier on the via sidewalls.

FIG. 5 depicts a single damascene interconnect that comprises a pre-deposited diffusion barrier and a combination of intermetallic conductor and dielectric compound on the via sidewalls.

FIG. 6 illustrates a method 600 of forming an interconnect according to embodiments of the present disclosure.

### DETAILED DESCRIPTION

Interconnects between lines of conductors (e.g., copper lines) are often formed with vias that span between a bottom conductor line and a top conductor line. These vias can be formed in a dual damascene process and a single damascene process. In a single damascene process, the interconnect via is filled in a first fill process, and the top conductor line is filled in a second, separate fill process. In a dual damascene process, the via and top conductor line are typically formed in a single fill process.

Filling a via and top conductor line in a dual damascene, single-fill process may be beneficial due to reducing the overall number of steps required to form the interconnect. Specifically, for example, dual damascene processes avoid a need to perform planarization of the via metal before forming the top conductor line. However, dual damascene processes often do not scale well to use cases in which vias and conductor lines of very small dimensions are necessary. Thus, in many use cases in modern interconnects, dual damascene vias are not precise enough to reliably fill via gaps, negatively affecting yields of the products in which those interconnects are integrated.

Single damascene fill processes, on the other hand, are able to more precisely fill via gaps in use cases with very fine dimensions. For this reason, single damascene fill processes are often used when forming interconnects in many modern products.

However, as noted earlier, single damascene fill processes typically involve preparing the interconnect for forming the top conductor line after filling the via. This typically requires performing a planarization process, such as chemical mechanical planarization (CMP), on the metal conductor with which the via was filled. This planarization process typically results in the surface of the via metal conductor and the surface of the dielectric that surrounds the via forming a single coplanar surface on which the top layer of the interconnect (the top conductor line and surrounding dielectric can be formed).

However, planarizing the via metal conductor can, in some instances, result in negative side effects. For example, common conductors used in interconnect vias include copper, tungsten and cobalt. However, these common conductors are often particularly susceptible to galvanic corrosion that can be caused by the planarization process. This can cause the top surface of the via conductor to recess during planarization more than intended. Recess of the via conductor can unfortunately cause poor contact with the top line conductor, resulting in poor yield of the products into which those interconnects are integrated.

Utilization of common conductors, such as copper, cobalt, and tungsten, for interconnect vias can also lead to performance issues if those common conductors are allowed to contact dielectric at the via sidewalls. Specifically, copper, cobalt, and tungsten and dielectric can diffuse together over time, increasing the resistance of the via structure. This can sometimes be avoided by coating via sidewalls with diffusion-barrier materials such as tantalum nitride (TaN) or titanium nitride (TiN). These diffusion-barrier materials have relatively high resistivity and act to isolate the via conductor from the surrounding dielectric. However, deposition of these diffusion barriers on the via sidewalls can also result in deposition of the diffusion barrier upon the via bottom (i.e., on the surface of the bottom conductor line). Because of the diffusion barrier's relatively high resistivity, this deposition on the bottom conductor line increases the resistance between the bottom conductor line and the via conductor, which decreases the performance of the interconnect overall.

Embodiments of the present disclosure address some of the issues identified above by presenting a single-damascene interconnect (i.e., an interconnect formed through a single-damascene process) with a via that is filled with a low resistivity metal conductor with high corrosion resistance. In some embodiments, the high corrosion resistance of these metal conductors may reduce or eliminate galvanic corrosion during the planarization of the metal conductor after filling the via.

For example, in some embodiments of the present disclosure, an interconnect via may be filled with a low-resistivity noble metal conductor, such as a platinum group metal. Platinum group metals, in addition to being naturally resistant to galvanic corrosion, is also resistant to diffusion into dielectric at the via sidewall. Thus, in these embodiments, no diffusion barrier may be necessary, and thus issues regarding high-resistivity diffusion barrier being inadvertently formed between the bottom conductor line and the via conductor may be avoided.

In some embodiments of the present disclosure, an interconnect via may be filled with an intermetallic conductor such as Al₂Cu, CuSn, Cuin, TiAl, NiAl, Ti₂Al, NiAl, Ni₃Al, Al₃Ti, MoSi₂, CuAl, CoTix CuAuZn, TiNi, ScAl3, and CuAlNi. These and some other intermetallic conductors are resistant to galvanic corrosion that may otherwise occur during chemical mechanical planarization of the via conductor metal when preparing the interconnect for application of the top conductor line. Further, these and some other intermetallic conductors can react with dielectric that surrounds the vial wall during that planarization process. As a result a via filled with Al₂Cu, for example, may react with the via sidewalls formed by a dielectric layer such as SiCOH. This reaction may cause the sidewalls of the via to be lined with a layer of native oxide. For example, an aluminum oxide (e.g., AlO, Al₂O₃) native oxide may form between Al₂Cu and surrounding dielectric SiCOH. In other words, a barrier of aluminum oxide (also referred to generically herein as AlOx) may be formed between the Al₂Cu via conductor and the SiCOH dielectric layer. This AlOx barrier may act similarly to a diffusion barrier, and may prevent diffusion between the via conductor and surrounding dielectric layer during device operation.

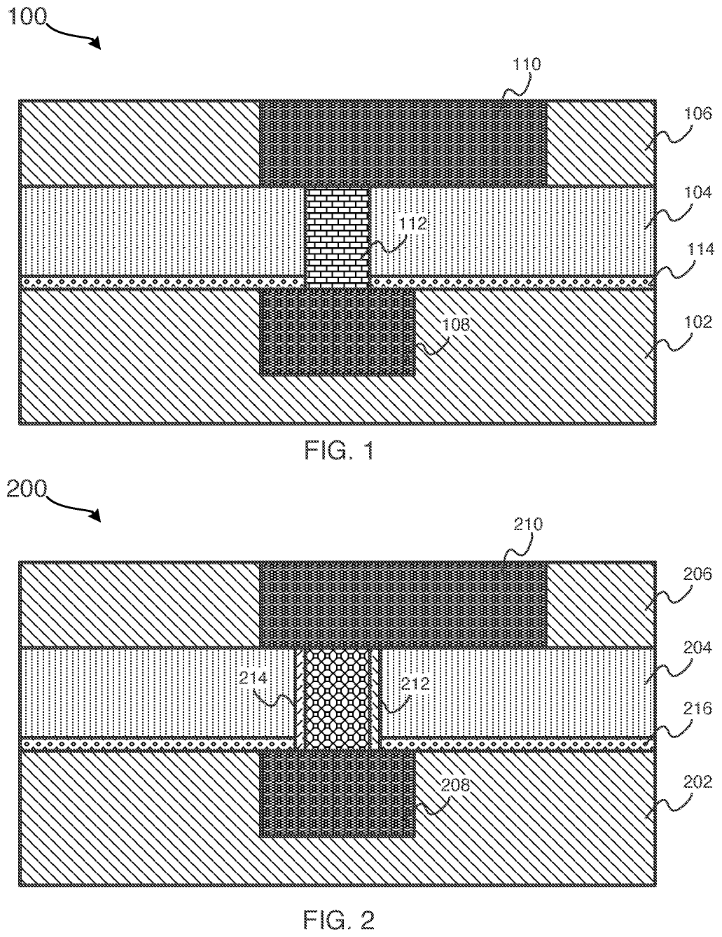

FIG. 1, for example, depicts a single damascene interconnect 100 that comprises a via filled with a noble metal. Interconnect 100 includes a bottom layer dielectric 102, middle layer dielectric 104, and top layer dielectric 106. In some embodiments, dielectrics 102-106 may all be the same dielectric material, whereas in other embodiments one or more dielectrics 102-106 may include a different material than the other dielectrics. For example, middle layer dielectric 104 could be composed of SiCOH, and dielectrics 102 and 106 could be composed of SiCOH as well or of another dielectric material. In some embodiments, dielectrics used for dielectric layers 102-106 could include SiNCH and SiCNOH.

Single damascene interconnect 100 also includes bottom conductor line 108 and top conductor line 110. Conductor lines 108 and 110 may be composed of, for example, copper (Cu), a copper alloy (e.g., CuMn, CuAl), a noble metal, tungsten, Al₂Cu, or cobalt (Co).

Via conductor 112 connects bottom conductor line 108 and top conductor line 110. Etch stop 114 is formed upon bottom layer dielectric 102. Etch stop may have been formed upon bottom layer dielectric 102 to protect bottom layer dielectric 102 in instances in which the etch that formed the via into which via conductor 112 is added was unaligned with conductor line 108, potentially overlapping with bottom layer dielectric 102. Via conductor 112 protrudes through etch stop 114. As noted above, via conductor 112 takes the form of, in the illustrated embodiment, a noble metal. Specifically, for example, via conductor 112 could take the form of ruthenium, rhodinium, palladium, osmium, iridium, or platinum. In some embodiments, via conductor 112 could also take the form of a metal silicide, such as CoSix or MoSix. Because these metals are naturally resistant to galvanic corrosion, no galvanic corrosion may occur when planarizing interconnect 100 to prepare for formation of top layer dielectric 106 and top conductor line 110.

Further, because these metals are also corrosion resistant, no resistant diffusion barrier may be necessary between via conductor 112 and middle layer dielectric 104. This may also prevent diffusion barrier from forming in the via on top of bottom conductor line 108, which would otherwise increase the resistivity between bottom layer dielectric 108 and via conductor 112.

Of note, in some embodiments an adhesion layer may be applied to the dielectric 106 sidewalls of the via before filling with via conductor 112 in order to encourage adhesion of the via metal to dielectric 104. However, such adhesion barriers may be thinly formed with material that is not electrically resistant, and thus may not significantly affect the conduction between via metal 112 and lower conductor line 108.

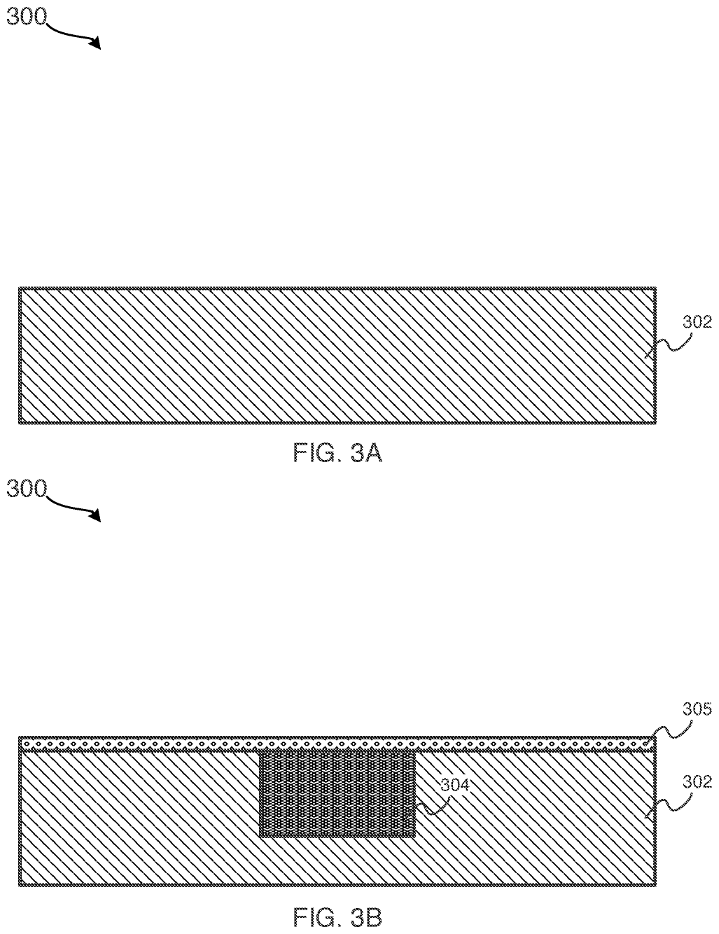

FIG. 2 provides a second example of an embodiment of the present disclosure. FIG. 2 depicts single damascene interconnect 200, which comprises a via filed with an intermetallic conductor. Similar to interconnect 100, interconnect 200 includes a bottom layer dielectric 202, middle layer dielectric 204, and top layer dielectric 206, bottom conductor line 208, top conductor line 210, and etch stop 216. These components may take the same form as their corresponding counterparts in FIG. 1.

Via conductor 212, on the other hand, is formed of an intermetallic metal. For example, via conductor 212 could be composed of Al₂Cu, CuSn, CuIn, TiAl, NiAl, Ti₂Al, NiAl, Ni₃Al, Al₃Ti, MoSi₂, CuAlNi, CuAuZn, TiNi, CoTix and CuAlNi. Because these intermetallics are naturally resistant to galvanic corrosion, no galvanic corrosion may occur when planarizing interconnect 200 to prepare for formation of top layer dielectric 206 and top conductor line 210. However, these intermetallic conductors may interact with middle layer dielectric 204 to form a self-forming barrier layer 214 (sometimes referred to herein as “self-forming layer 214”).

Self-forming layer 214 may take the form of a combination of via conductor 212 and middle layer dielectric 204 (i.e., a combination of the elements out of which via conductor 212 and middle layer dielectric 204 are formed). These combinations may typically take the form of a native oxide. For example, if via conductor 212 were formed of Al₂Cu and middle layer dielectric 204 were formed of SiCOH, self-forming layer 214 may take the form of AlOx (e.g., a mixture of AlO and Al₂O₃). Depending on the nature of middle layer dielectric and via conductor 212, native oxide forms of self-forming layer 214 could be composed of, for example, MnOx, MnOxSix, SnOx, or SnOxSix.

Of note, self-forming barrier 214 may also take the form of a single component of via conductor 212 that has diffused into the edge of middle layer dielectric 204 and separated from the intermetallic body of via conductor 212. For example, if via conductor 212 were composed of CoTix, self-forming barrier 214 may be composed of Ti which has segregated at the interface of via conductor 212 and middle layer dielectric 204.

Self-forming layer 214 may be formed spontaneously during deposition of via conductor 212 and may provide sufficient diffusion resistance to via conductor 212 such that no other diffusion barrier would be necessary for interconnect 200. In other words, self-forming layer 214 may prevent diffusion from occurring between via conductor 212 and middle layer dielectric 204 during operation of interconnect 200. As a result, no pre-deposited diffusion barrier may be necessary between via conductor 212 and middle layer dielectric 204. This would also prevent diffusion barrier from inadvertently forming in the via on top of bottom conductor line 208, which would otherwise increase the resistivity between bottom layer dielectric 208 and via conductor 212.

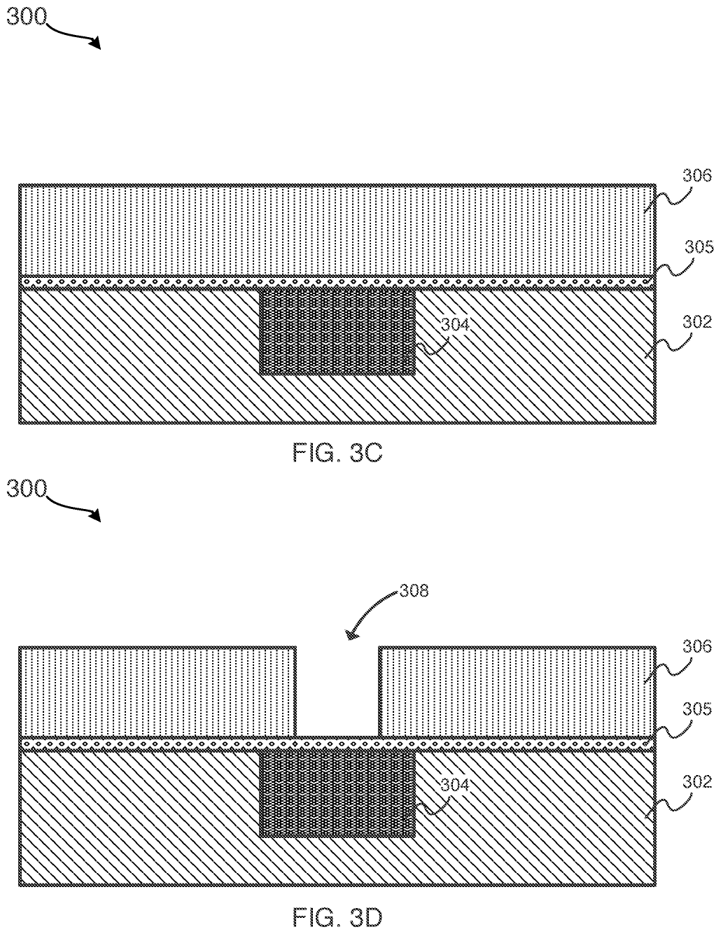

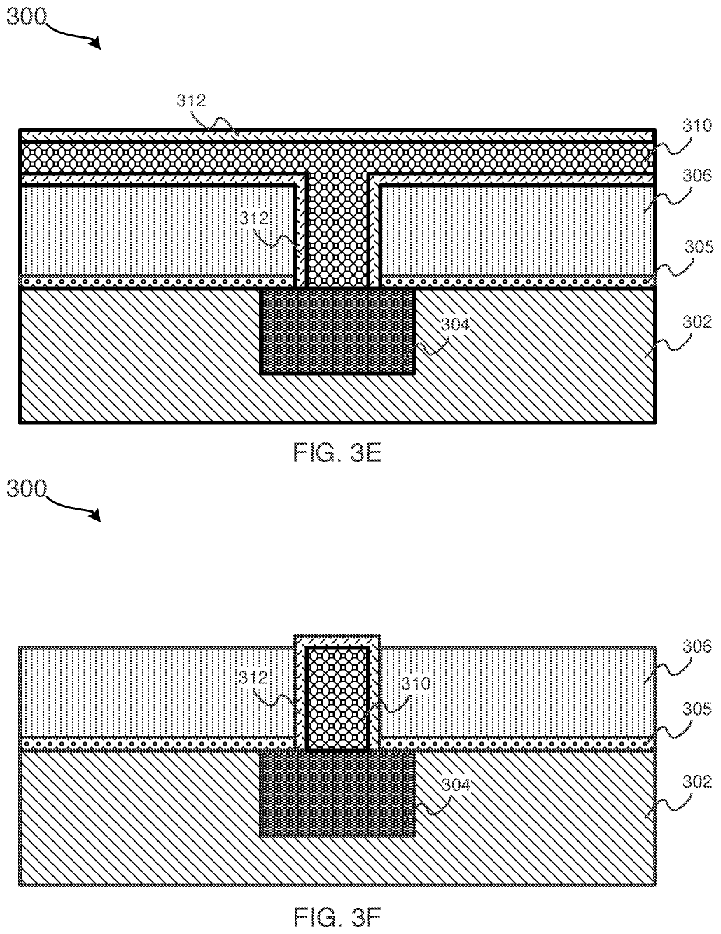

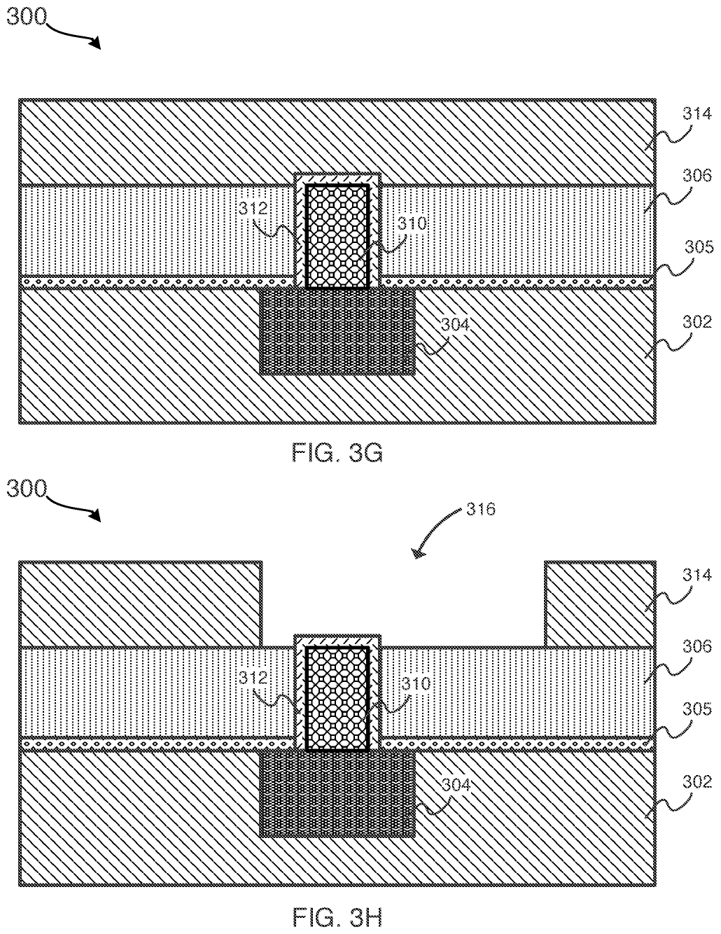

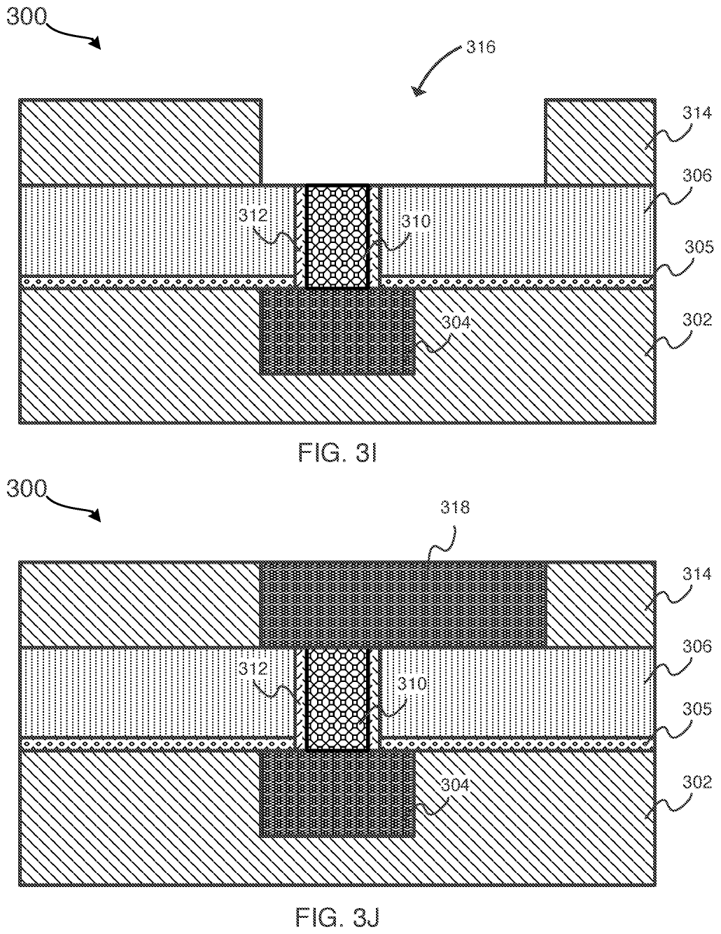

For the sake of clarity, FIGS. 3A-3J present a process of forming a single damascene interconnect 300 that comprises a via filled with an intermetallic conductor and self-forming barrier layer. FIG. 3A depicts interconnect 300 after a first stage of formation. In FIG. 3A, lower layer dielectric 302 has been formed. Lower layer dielectric 302 may resemble, for example, lower layer dielectrics 102 and 202.

FIG. 3B depicts interconnect 300 after lower conductor line 304 has been formed within lower layer dielectric 302. Lower conductor line 304 may have been formed, for example, by applying a mask to the top surface of lower layer dielectric 302 and performing a directional etch (e.g., a reactive ion etch) on interconnect 300, producing a well in lower layer dielectric 302. This well may then have been filled with conductive material, such as copper. Excess conductive metal may then have been removed through chemical mechanical planarization to the top surface of lower layer dielectric 302.

FIG. 3B also depicts interconnect 300 after etch stop 305 has been formed upon lower layer dielectric 302 and lower conductor line 304. As noted with respect to FIG. 1, etch stop 305 may protect lower layer dielectric 302 in subsequent formation stages if the formation of a via well overlaps with lower layer dielectric 302.

FIG. 3C depicts interconnect 300 after application of middle layer dielectric 306. Middle layer dielectric 306 may resemble, for example, middle layer dielectrics 104 and 204. FIG. 3D depicts interconnect 300 after via 308 has been formed within middle layer dielectric 306. Via 308 may have been formed, for example, by applying a mask throughout the surface of middle layer dielectric 306 except for the location of via 308 and applying a directional etch to the unmasked portion of middle layer dielectric 306 down to etch stop 305 atop lower conductor line 304. The mask may then be removed from middle layer dielectric 306. As illustrated, via 308 has been formed in the center of lower conductor line 304. If, however, the unmasked portion of middle layer dielectric 306 (and thus via 308) had not been aligned with conductor 304 and partially overlapped lower layer dielectric 302, etch stop 305 would have protected lower layer dielectric 302 from the directional etch.

FIG. 3E depicts interconnect 300 after via 308 (not visible in FIG. 3E) is filled by via conductor 310. Via conductor 310 is, in this embodiment, an intermetallic conductor, and may be composed of any of the same materials out of which via conductor 212 may be composed (e.g., Al₂Cu, CuSn, CuIn, TiAl, NiAl, Ti₂Al, NiAl, Ni₃Al, Al₃Ti, MoSi₂, CuAlNi, CuAuZn, TiNi, and CuAlNi). Via conductor 310, as illustrated, has been overfilled over the surface of middle layer dielectric 306. Excess via conductor 310 may therefore be removed by chemical mechanical planarization.

FIG. 3E also depicts self-forming barrier 312 that has formed spontaneously both at the interface of via conductor 310 and dielectric middle layer dielectric 306 and at the interface of via conductor 310 and environmental air. As noted previously, barrier 312 at the interface with middle layer dielectric 306 is composed of a combination of the elements that form via conductor 310 and middle layer dielectric 306. Thus, depending on the materials within via conductor 310 and middle layer dielectric 306, barrier 312 may be composed of, for example, AlOx, MnOx, MnOxSix, SnOx, or SnOxSix.

FIG. 3F depicts interconnect 300 after chemical mechanical planarization of excess via conductor has completed. As illustrated, planarization has continued until all of excess via conductor 310 and barrier 312 have been removed from the top surface of middle layer dielectric 306. This may be accomplished, for example, if an etchant used in chemical mechanical planarization is selective to middle layer dielectric 306 with respect to via conductor 310 and barrier 312, causing middle layer dielectric 306 to act as an etch stop. This may also be accomplished, in some embodiments, if the etchant used is not selective to middle layer dielectric 306, but if planarization is timed such that only an acceptable amount of middle layer dielectric 306 has been removed. In either embodiment, barrier 312 may continue to form at the top of via conductor 310 during planarization due to reacting with an oxidant agent in the CMP slurry. This formation may protect via conductor 310 from being etched within the via and below the surface of middle layer dielectric 306.

This would initially result in the top surfaces of via conductor 310 and barrier 312 being coplanar with the top surface of middle layer dielectric 306. However, in some use cases via conductor 310 would react with environmental oxygen immediately following planarization, forming a small layer of native dielectric on top of via conductor 310. This top layer is presented in FIG. 3F for the purpose of understanding. At this point, via conductor 310 and barrier 312 may otherwise resemble via conductor 212 and barrier 214 of FIG. 2.

FIG. 3G depicts interconnect 300 after top layer dielectric 314 has been applied to the top surfaces of middle layer dielectric 306, via conductor 310, and barrier 312. Top layer dielectric 314 may be used to provide a template in which a top conductor line is formed. FIG. 3H, for example, depicts interconnect 300 after conductor-line well 316 has been formed within top layer dielectric 314. Conductor-line well 316 may have been formed, for example, by applying a mask to the top surface of top layer dielectric 314 in all areas not intending to be occupied by conductor-line well 316 (for example, as illustrated in FIG. 3H). A directional etch could then be performed on top layer dielectric 314 to form conductor-line well 316. In some embodiments, an etchant may be used that is selective to top layer dielectric 314 with respect to at least one of middle layer dielectric 306, via conductor 310, and barrier 312. This may facilitate terminating the etching process before any of those components have been partially removed. At the point illustrated in FIG. 3J, top layer dielectric may resemble top layer dielectrics 106 and 206.

FIG. 31 depicts interconnect 300 after excess self-forming barrier 312 on top of via conductor 310 has been sputtered off. In some embodiments, this step may be performed in a vacuum chamber to prevent further reaction between via conductor 310 and oxygen in the surrounding environment. After self-forming barrier 312 is removed from the top of via conductor 310, interconnect 300 is ready for the application of a top conductor line.

FIG. 3J, therefore, depicts interconnect 300 after top conductor line 318 has been formed within well 316 within top layer dielectric 314. This may be accomplished, for example, by applying a conductor material, such as copper, within conductor-line well 316. This may result in excess conductor material being applied over conductor-line well 316 and on the top surface of top layer dielectric 314. That excess conductor material may be removed by a planarization process that is selective to top layer dielectric 314 with respect to conductor line 318, causing top layer dielectric 314 to act as an etch stop. This may also be accomplished by timing the planarization process to terminate after an expected amount of top conductor line 318, and potentially some of top layer dielectric 314, have been removed. At this point, top conductor line 318 may resemble top conductor lines 110 and 210 of FIGS. 1 and 2, and interconnect 300 may resemble interconnect 200 of FIG. 2.

As noted above, some embodiments of the present disclosure may obviate the need for a diffusion barrier being applied to the sidewalls of a via before filling the via with a via conductor. However, some benefits of the present disclosure can also be gained in embodiments in which a diffusion barrier is pre applied.

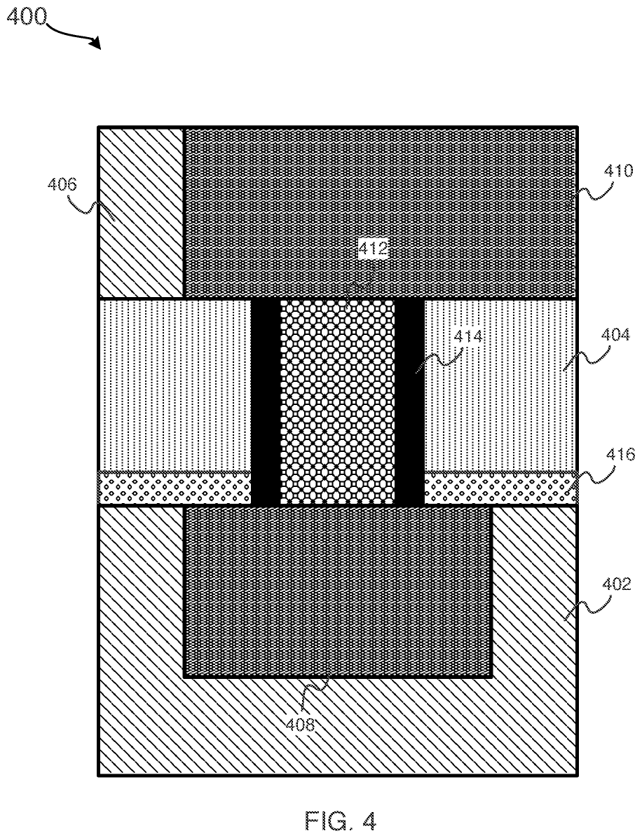

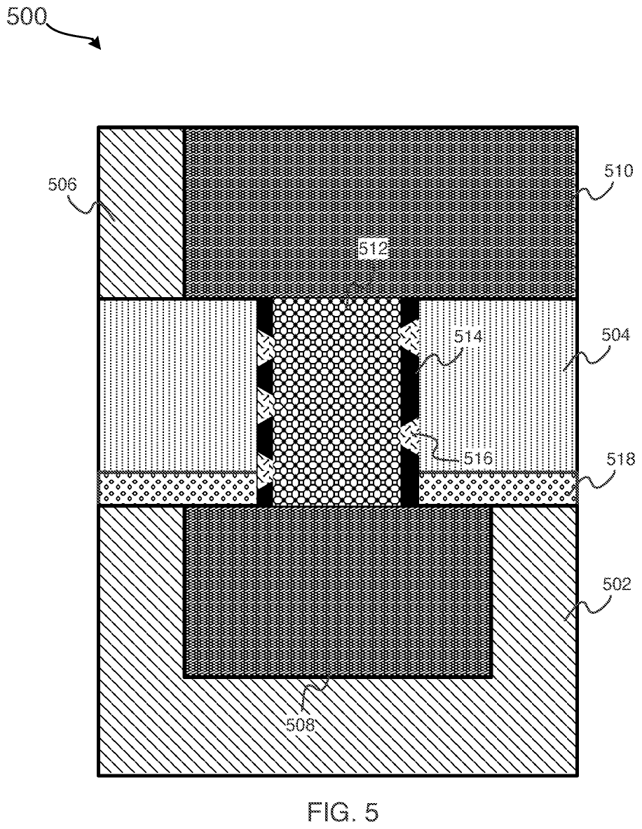

FIG. 4, for example, illustrates a magnified view of interconnect 400, which resembles interconnects 100 and 200 in several aspects. For example, interconnect 400 contains lower layer dielectric 402, middle layer dielectric 404, upper layer dielectric 406, bottom conductor line 408, top conductor line 410, via conductor 412, and etch stop 416. Lower layer dielectric 402, middle layer dielectric 404, upper layer dielectric 406, bottom conductor line 408, top conductor line 410 may resemble their respective counterparts in FIGS. 1 and 2. Further, via conductor 412 may resemble via conductor 112 of FIG. 1 or via conductor 212 of FIG. 2. In other words, via conductor 412 may take the form of a noble metal via conductor or an intermetallic conductor via conductor.

Unlike interconnects 100 and 200, interconnect 400 also includes pre-deposited diffusion barrier 414. Pre-deposited diffusion barrier 414 may be a highly resistive diffusion barrier, such as tantalum nitride (TaN) or titanium nitride (TiN). Pre-deposited diffusion barrier 414 may act to prevent diffusion between via conductor 412 and middle layer dielectric 404. This may be particularly useful, for example, in embodiments in which via conductor 412 is an intermetallic conductor but is not expected to form a self-forming barrier (e.g., a native oxide barrier) that is complete enough to sufficiently prevent diffusion.

Of note, the resistance to galvanic corrosion of via conductor 412 may be beneficial even when pre-deposited diffusion barrier 414 is applied. Specifically, the resistance to galvanic corrosion of via conductor 412 may prevent formation of a galvanic local battery during CMP of via conductor 412. Without the resulting galvanic corrosion, the connection between via conductor 412 and top conductor line 410 may be more complete, increasing the performance of interconnect 400.

As noted above, using a pre-deposited diffusion barrier may sometimes cause excess diffusion barrier being formed on the top surface of a bottom conductor line. This excess diffusion barrier, therefore, is located between the bottom conductor line and the via conductor in the finished interconnect. However, because of the resistive nature of most diffusion barriers, excess diffusion barrier between a conductor line and via conductor can negatively affect the performance of the interconnect. Thus, in such use cases, it is often beneficial to use as thin layer of pre-deposited diffusion barrier as possible, reducing the potential resistance between the bottom conductor line and the via conductor. However, in some of these use cases, using a very thin pre-deposited diffusion barrier can result in an incomplete barrier on the via sidewalls, resulting in some gaps in which diffusion can still occur between a via conductor and the surrounding middle layer dielectric. In some embodiments of the present disclosure, an intermetallic via conductor may be used to fill gaps in a thin layer of pre-deposited diffusion barrier. This process may be referred to as scabbing, healing, or self-healing of the pre-deposited diffusion barrier, and will be illustrated in FIG. 5.

FIG. 5 illustrates such an embodiment. Similar to FIG. 4, FIG. 5 illustrates a magnified view of interconnect 500, which also resembles interconnects 100 and 200 in several aspects. Interconnect 500 contains lower layer dielectric 502, middle layer dielectric 504, upper layer dielectric 506, bottom conductor line 508, top conductor line 510, via conductor 512, and etch stop 518. Lower layer dielectric 502, middle layer dielectric 504, upper layer dielectric 506, bottom conductor line 508, top conductor line 510 may resemble their respective counterparts in FIGS. 1 and 2. Via conductor 512 resembles via conductor 212. In other words, via conductor is formed of an intermetallic conductor.

Similar to interconnect 400, interconnect 500 includes a pre-deposited diffusion barrier 514. However, unlike pre-deposited diffusion barrier 414 of FIG. 4, pre-deposited diffusion barrier 514 was applied in a very thin layer that resulted in several gaps being formed in pre-deposited diffusion barrier 514. However, because via conductor 512 takes the form of an intermetallic conductor that reacts with middle layer dielectric 504, those gaps were filled by a combination of via conductor 512 and middle layer dielectric 504. Instances of this combination are filling these gaps are illustrated in FIG. 5 by native-oxide instances 516.

In other words, in the embodiments of FIG. 5, the pre-applied diffusion barrier is self healing due to the inclusion of an intermetallic via conductor. Of note, while not illustrated with respect to interconnect 500, the same self-healing effect could also be exhibited in embodiments in which an adhesion layer is applied to the inner sidewalls of the via before applying an intermetallic via conductor. In these embodiments, gaps in the adhesion layer may also be filled and healed with native-oxide scabbing, similar to native-oxide instances 516.

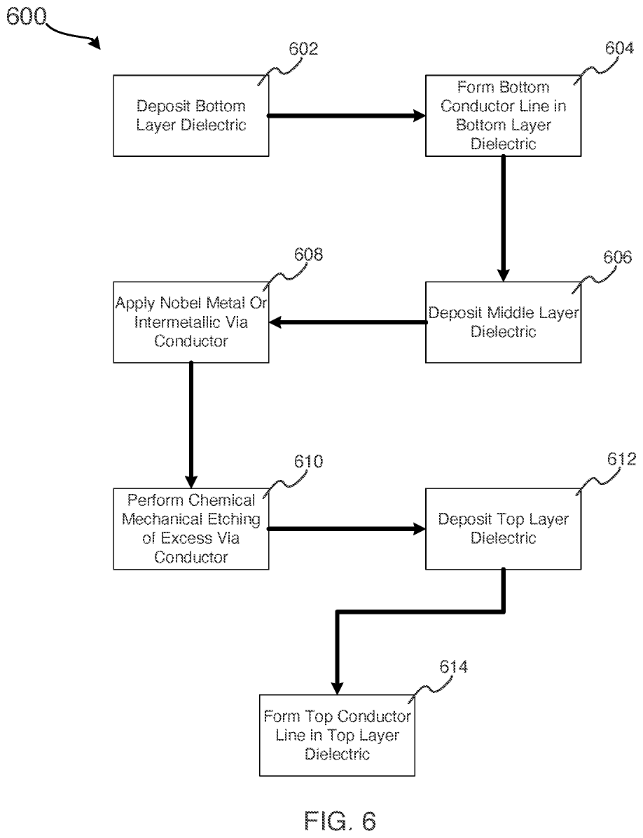

FIG. 6 illustrates a method 600 of forming an interconnect according to embodiments of the present disclosure. Method 600 could be used, for example, to create any of interconnects 100, 200, 300, 400, or 500.

Method 600 begins in block 602, in which a bottom layer dielectric is deposited. This bottom layer dielectric may resemble a bottom layer dielectric from interconnects 100-500. Block 602 may result, for example, in an interconnect similar to interconnect 300 as illustrated FIG. 3A.

Method 600 continues in block 604, in which a bottom conductor line is formed within the bottom layer dielectric. This may include, for example, applying a mask to the bottom layer dielectric and etching the bottom layer dielectric in the locations not covered by the mask. This would create a well for the bottom conductor line, which could then be deposited within the well, after which excess conductor could be removed with CMP. Block 604 may result, for example, in an interconnect similar to interconnect 300 as illustrated in FIG. 3B.

Method 600 continues in block 606 in which a middle layer dielectric is deposited upon the bottom layer dielectric and the bottom conductor line. In some embodiments, depositing a middle layer dielectric upon a bottom layer dielectric may deposit the dielectric of the middle-layer dielectric directly upon a surface of the dielectric for the bottom layer dielectric. In other embodiments, depositing a middle layer dielectric upon the bottom layer dielectric may actually deposit the dielectric of the middle-layer dielectric upon an etch stop layer that is formed upon the bottom layer dielectric. In these embodiments, block 606 may also include depositing the etch stop layer prior to depositing the middle layer dielectric. This middle layer dielectric may resemble a middle layer dielectric from interconnects 100-500. Block 606 may result, for example, in an interconnect similar to interconnect 300 as illustrated in FIG. 3C.

Method 600 continues in block 608 in which a via conductor is applied. This via conductor can be formed by applying a mask to the middle layer dielectric and etching the middle layer dielectric in the locations not covered by the mask. This would result in a via into which a via conductor could be deposited. As noted, this via conductor could be a noble metal, similar to via conductor 112, or an intermetallic via conductor, similar to via conductor 212. In embodiments in which an intermetallic via conductor is applied in block 608, that intermetallic via conductor may form a self-forming diffusion barrier (e.g., native oxide barrier) by reacting with the middle layer dielectric that forms the inner sidewalls of the via.

Of note, block 608 may also include depositing a pre-deposited diffusion barrier within the via before filling the via with the via conductor. In such embodiments, block 608 may result in a diffusion barrier that resembles pre-deposited diffusion barrier 414.

Method 600 continues in block 610, in which excess via conductor is removed through a chemical mechanical etching process.

Method 600 continues in block 612, in which a top layer dielectric 612 is formed upon the planarized via conductor and middle layer dielectric. This top layer dielectric may resemble a top layer dielectric from interconnects 100-500. In some embodiments, block 612 may also include etching, in a vacuum chamber, excess self-forming barrier from the top surface of an intermetallic via conductor in preparation for the top conductor line.

Method 600 concludes in block 614 in which a top conductor line is formed within the top layer dielectric. In some embodiments, this block may include patterning a well for the top conductor line in the top layer dielectric, as illustrated in FIG. 3H. Block 614 may also include inserting the interconnect into a vacuum chamber and sputtering off excess self-forming barrier layer from the top of the via conductor. In these embodiments, the top conductor line may be applied within the well while the interconnect is within the vacuum chamber, preventing further reaction between via conductor 310 and oxygen in the surrounding environment.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments.

Of note, the relative sized of various components of the figures is presented as such for the purposes of illustration only. Thus, the specific relative sizes of components in any of FIGS. 1-5 should not be interpreted as intending to suggest limitations or restrictions on the embodiments of this disclosure in practice. For example, the width of barrier 312 may be, in practice, significantly thinner relative to the width of via conductor 310 than what is represented in FIGS. 3F-3J.

The terminology used herein was chosen to best explain the principles of the embodiments, the practical application or technical improvement over technologies found in the marketplace, or to enable others of ordinary skill in the art to understand the embodiments disclosed herein.

What is claimed is:

1. A single-damascene interconnect comprising:
a first conductor line;
a second conductor line;
a via connecting the first conductor line and second conductor line, wherein the via is filled with a low resistivity metal conductor with high corrosion resistance, and wherein the metal conductor is not the same material as the first or second conductor lines.

2. The single-damascene interconnect of claim 1, wherein the metal conductor is a noble metal.

3. The single-damascene interconnect of claim 2, wherein the noble metal is selected from a group consisting of ruthenium, iridium, platinum, and rhodium.

4. The single-damascene interconnect of claim 1, wherein the metal conductor is an intermetallic conductor.

5. The single-damascene interconnect of claim 3, wherein the sidewalls of the via comprise a barrier layer.

6. The single-damascene interconnect of claim 5, wherein the barrier layer comprises a self-forming barrier layer.

7. The single-damascene interconnect of claim 6, wherein the self-forming barrier layer comprises a native-oxide combination of the intermetallic conductor and a dielectric compound that surrounds the via.

8. The single-damascene interconnect of claim 7. wherein the intermetallic conductor is CuAl₂, wherein the dielectric compound is SiCOH, and the combination is AlOx.

9. The single-damascene interconnect of claim 5, wherein the barrier layer comprises a pre-deposited diffusion barrier.

10. The single-damascene interconnect of claim 9, wherein the barrier layer also comprises a self-forming combination of the intermetallic conductor and a dielectric compound that surrounds the via.

11. The single-damascene interconnect of claim 5, wherein the barrier layer consists of a single component of the intermetallic conductor.

12. The single-damascene interconnect of claim 11, wherein the intermetallic conductor comprises CoTix, and wherein the barrier layer consists of Ti.

13. A method of forming an interconnect, the method comprising:
depositing a middle layer dielectric upon a bottom layer dielectric;
forming a via well within the middle layer dielectric; and
applying an intermetallic via conductor within the via well.

14. The method of claim 13, wherein an element of the intermetallic via conductor combines with an element of the middle layer dielectric to form a self-forming barrier layer.

15. The method of claim 13, wherein an element of the intermetallic via conductor segregates from the intermetallic via conductor at an interface of the intermetallic via conductor and the middle layer dielectric.

16. The method of claim 13, further comprising depositing a top layer dielectric upon the middle layer dielectric and the intermetallic via conductor.

17. The method of claim 16, further comprising forming a conductor well within the top layer dielectric.

18. The method of claim 17, further comprising sputtering, in a vacuum chamber, excess self-forming barrier layer from the intermetallic via conductor.

19. The method of claim 17, further comprising forming, in a vacuum chamber, a top conductor line in the conductor well.

20. The method of claim 13, further comprising forming a pre-applied diffusion barrier on the walls of the via well, wherein an element of the intermetallic via conductor combines within an element of the middle layer dielectric within a gap in the pre-applied diffusion barrier.
